(19) United States
(12) Patent Application Publication
(10) Pub. No.: US 2025/0038560 A1
(43) Pub. Date: Jan. 30, 2025

(54) LINK CAPACITOR DISCHARGE CIRCUIT WITH TEMPERATURE CONTROL

(71) Applicant: GKN Automotive Limited, Birmingham (GB)

(72) Inventor: Eric Wyman, Mt. Pleasant, MI (US)

(21) Appl. No.: 18/225,185

(22) Filed: Jul. 24, 2023

(51) Int. Cl. H02J 7/00; B60L 50/60; H02J 7/34

(52) U.S. Cl. CPC H02J 7/007192; B60L 50/60; H02J 7/0063; H02J 7/345; B60L 2210/40; H02J 2207/20

(57) ABSTRACT

In at least some implementations, a discharge circuit for an electric vehicle, includes a link capacitor, a resistive load, a discharge switch coupled to the link capacitor and to the resistive load so that the link capacitor is coupled to the resistive load when the discharge switch is closed to enable discharge of the link capacitor, and a discharge interrupt assembly. The discharge interrupt assembly has a sensing resistor connected in series with the resistive load, and a temperature circuit. The temperature circuit has an input connected to the sensing resistor and an output, and the discharge interrupt circuit is responsive to a voltage at the output of the temperature circuit to open the discharge switch when the voltage from the temperature circuit is higher than a threshold.

### TECHNICAL FIELD

The present disclosure relates generally to link capacitor discharge circuit with temperature control.

### BACKGROUND

Electric vehicles include batteries that provide power to one or more motors to drive the vehicle wheels. Electric vehicles typically include a large capacitor between the positive and negative terminals of a high voltage input, and this capacitor must be discharged quickly during vehicle shutdown, and this may be done through a resistive load. During initial discharge, the power dissipated in the resistive load is very large and considerable heat is generated. It can be difficult and expensive to accurately monitor the temperature of the resistive load and protect against damage to components if, for example, the vehicle battery or batteries still are connected or if there is too much energy stored in the capacitor which may cause a longer discharge event and higher temperature.

### SUMMARY

In at least some implementations, a discharge circuit for an electric vehicle, includes a link capacitor, a resistive load, a discharge switch coupled to the link capacitor and to the resistive load so that the link capacitor is coupled to the resistive load when the discharge switch is closed to enable discharge of the link capacitor, and a discharge interrupt assembly. The discharge interrupt assembly has a sensing resistor connected in series with the resistive load, and a temperature circuit. The temperature circuit has an input connected to the sensing resistor and an output, and the discharge interrupt circuit is responsive to a voltage at the output of the temperature circuit to open the discharge switch when the voltage from the temperature circuit is higher than a threshold.

In at least some implementations, the sensing resistor is connected in series with the discharge switch.

In at least some implementations, an amplifier is provided between the sensing resistor and the temperature circuit.

In at least some implementations, the link capacitor, resistive load, discharge switch and sensing resistor are connected in series.

In at least some implementations, the voltage at the output of the temperature circuit is a function of the temperature of the resistive load.

In at least some implementations, the temperature circuit includes a first resistor, a control capacitor connected in series with the first resistor, and a second resistor coupled in parallel with the control capacitor.

In at least some implementations, the discharge interrupt assembly includes a comparator coupled to the output of the temperature circuit, wherein the comparator is arranged to provide a first output when a voltage at the output of the temperature circuit is at a first threshold. In at least some implementations, the comparator is arranged to provide a second output when the voltage at the output of the temperature circuit is at a second threshold.

In at least some implementations, an electric vehicle includes a power source, a motor driven by electricity from the power source, an inverter, a link capacitor, a resistive load, a discharge switch, a sensing resistor, a temperature circuit and a discharge interrupt assembly. The inverter is coupled to the power source and the motor to convert a DC power output from the power source to AC power and to provide the AC power to the motor. The link capacitor is coupled in series between the power source and the inverter. The discharge switch is coupled to the link capacitor and to the resistive load so that the link capacitor is coupled to the resistive load when the discharge switch is closed to enable discharge of the link capacitor. The sensing resistor is arranged to receive current when current flows from the link capacitor to the resistive load. The temperature circuit has an input connected to the sensing resistor and an output. And the discharge interrupt assembly is responsive to a voltage at the output of the temperature circuit to open the discharge switch when the voltage from the temperature circuit is higher than a threshold.

In at least some implementations, the discharge interrupt assembly includes a comparator coupled in series with the temperature circuit output, wherein the comparator is arranged to provide an output when a voltage at the output of the temperature circuit is higher than a threshold.

In at least some implementations, an amplifier is coupled between the sensing resistor and the temperature circuit.

In at least some implementations, the temperature circuit includes a first resistor, a control capacitor connected in series with the first resistor, and a second resistor coupled in parallel with the control capacitor.

In at least some implementations, an electric vehicle includes a power source, a motor driven by electricity from the power source, an inverter coupled to the power source and the motor to convert a DC power output from the power source to AC power and to provide the AC power to the motor, a link capacitor coupled in series between the power source and the inverter, a resistive load, a discharge switch coupled to the link capacitor and to the resistive load so that the link capacitor is coupled to the resistive load when the discharge switch is closed to enable discharge of the link capacitor, a sensing resistor arranged to receive current when current flows from the link capacitor to the resistive load, a resistor-capacitor circuit having an input connected to the sensing resistor and an output, and a comparator. The comparator is coupled to the output of the resistor-capacitor circuit and to the discharge switch and arranged to open the discharge switch when a voltage from the resistor capacitor circuit is higher than a threshold.

In at least some implementations, the resistor-capacitor circuit includes a first resistor, a control capacitor connected in series with the first resistor, and a second resistor coupled in parallel with the control capacitor.

In at least some implementations, the sensing resistor is connected in series with the discharge switch.

In at least some implementations, the link capacitor, resistive load, discharge switch and sensing resistor are connected in series.

In at least some implementations, the voltage at the output of the resistor-capacitor circuit is a function of the temperature of the resistive load.

In at least some implementations, the comparator is arranged to provide a second output when the voltage at the output of the temperature circuit is at a second threshold.

### BRIEF DESCRIPTION OF THE DRAWINGS

The following detailed description of preferred embodiments and best mode will be set forth with reference to the accompanying drawings, in which:

FIG. 1 is a side view of a vehicle including an electric power supply and one or more electric motors to propel the vehicle:

FIG. 2 is a schematic diagram of components and subcircuits within an electrical system of the vehicle:

FIG. 3 is a partial circuit diagram showing an amplifier, temperature subcircuit and a comparator:

FIG. 4 is a partial circuit diagram showing the amplifier, temperature subcircuit and comparator within a larger portion of a circuit including a link capacitor and discharge switch; and

FIG. 5 is a flowchart of a method for controlling the discharge of a link capacitor.

### DETAILED DESCRIPTION

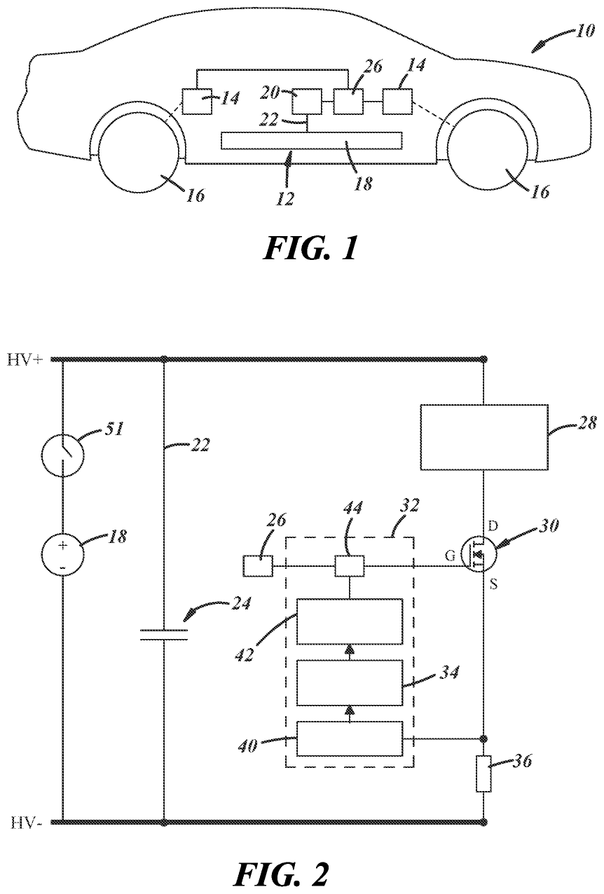

Referring in more detail to the drawings, FIG. 1 illustrates a vehicle 10 that include an electric power supply 12 that provides power to one or more motors 14 that drive the vehicle's wheels 16. The power supply 12 may include one or more rechargeable batteries 18 and an inverter 20 coupled to the batteries by a DC link 22. The inverter 20 converts the DC battery power to AC power and includes a DC-link capacitor 24 (FIG. 2) connected in parallel to the battery 18 to provide load balancing and energy storage in the system. To control the application of power to the motors 14, a controller/control system 26 that may include one or more microcontrollers is coupled between the power supply 12 and the motors 14 and provides current to the motors to drive the motors in a desired manner to propel the vehicle 10.

When vehicle operation is terminated, the link capacitor 24 needs to be discharged somewhat quickly to safely reduce the electrical power in the system. To do this, as shown in FIG. 2, a resistive load 28 is selectively connected to the link capacitor 24 by a discharge switch 30. The resistive load 28 may include an array of resistive elements having a desired total resistance. When the discharge switch 30 is in an open, non-conductive state, the link capacitor 24 is not connected to the resistive load 28 and when the discharge switch 30 is in a closed, conductive state, the link capacitor 24 is connected to and discharges energy to the resistive load 28. To control the state of the discharge switch 30, the switch is coupled to the control system 26 which provides a signal to close the discharge switch when discharge of the link capacitor 24 is desired.

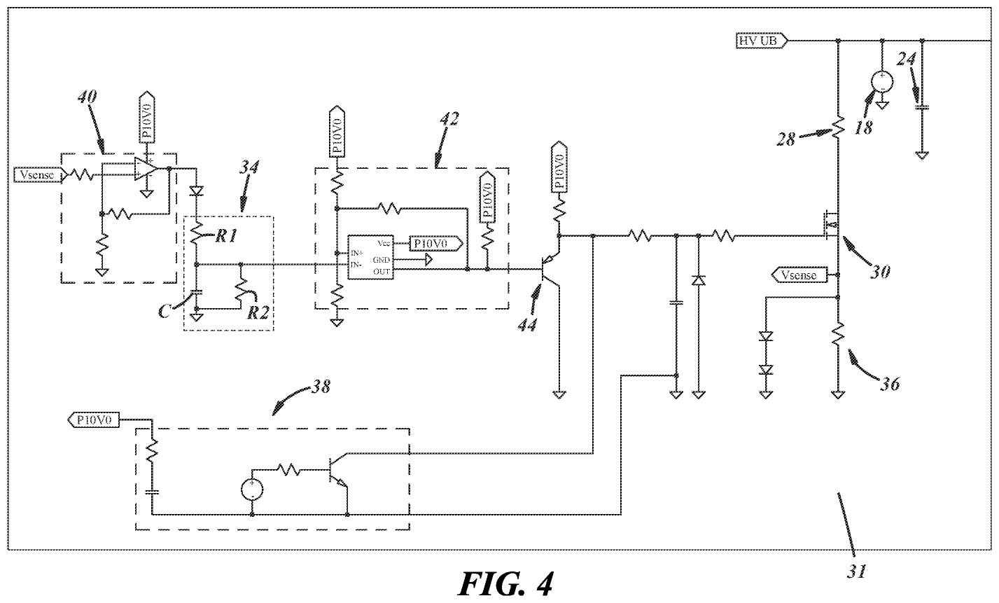

The energy discharge through the resistive load 28 is converted to heat which increases the temperature of the components of the resistive load 28 and adjacent components. The resistive load 28 may be designed to handle normal discharge cycles of the link capacitor 24, where the power dissipated by the resistive load 28 causes a predictable increase in system temperature, e.g. the temperature of the resistors, an associated circuit board 31 (FIG. 4) and adjacent components. But a fault in the system that causes more than a normal amount of energy to be dissipated through the resistive load 28 can unduly increase the system temperature. Such a fault in the system could, for example, cause additional power to be provided to the link capacitor 24 because, for example, the battery 18 remains connected to the link capacitor 24 due to a disconnection switch failure or other failure. In such a failure, the battery 18 would continue to provide power to the link capacitor 24 as the link capacitor is being discharged.

To limit the temperature of the resistive load 28 during a link capacitor discharge event, a discharge interrupt assembly 32 is provided. As shown in FIGS. 2-4, the discharge interrupt assembly 32 includes a temperature circuit 34 or subcircuit arranged to provide an output that is representative of the system temperature (e.g. of the resistive load and adjacent components). In at least some implementations, the discharge interrupt assembly 32 includes a sensing resistor 36 and the temperature circuit 34 includes a resistor-capacitor (RC) subcircuit. The sensing resistor 36 is connected in series with the resistive load 28 and to an input of the RC subcircuit 34. The RC subcircuit 34, as set forth in more detail below, is arranged to provide a voltage at its output that approximates the system temperature. The RC subcircuit output voltage can then be used to terminate a link capacitor discharge event when the RC subcircuit output voltage is above a threshold which indicates that the system temperature is at or above a threshold temperature. In this way, the maximum system temperature during a link capacitor discharge event can be controlled.

As shown in FIG. 2, the link capacitor 24 is connected in parallel across the terminals of the power supply (e.g. one or more batteries 18). The resistive load 28, discharge switch 30 and sensing resistor 36 are connected in series with each other and in parallel with the link capacitor 24. When the discharge switch 30 is closed and conductive, the link capacitor 24 is discharged to the resistive load 28 and current flows through the discharge switch 30 and sensing resistor 36. The discharge switch 30 may be any type of electronic switch controllable to change state as desired, for example, transistors, MOSFETs, and IGBTs, the state of which may be changed by a controller to control discharge of the link capacitor 24. Further, as shown in FIG. 4, a control interface 38 may be provided to control discharge of the link capacitor 24 in a desired manner, for example, using a pulse width modulated signal to provide a desired rate of link capacitor discharge in a normal discharge cycle.

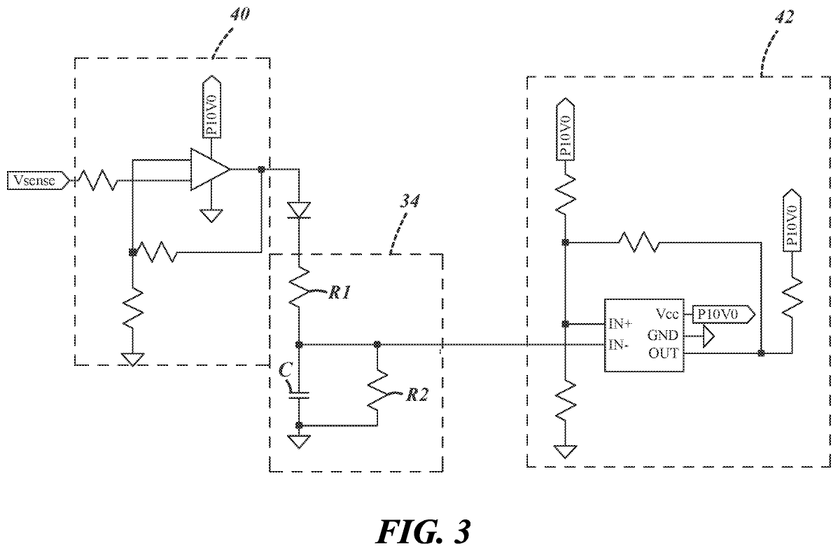

As shown in FIG. 4, the sensing resistor 36 may be connected between the discharge switch 30 and ground, and to the RC subcircuit 34. The sensing resistor 36 may have a relatively small resistance compared to the resistive load 28. In at least some implementations, the sensing resistor 36 has a resistance of between one ohm and ten ohms. The sensing resistor 36 may have a low resistance value to avoid excessive power/heat dissipation while having a large enough resistance value that the voltage generated at the sensing resistor is detectable by the protection system. These conditions usually end up requiring a sensing resistance value several orders of magnitude lower than the resistive load. When the discharge switch 30 is closed, current flows through the sensing resistor 36 and a voltage is generated that is at least somewhat proportional to the power dissipated by the resistive load 28. The generated voltage from the current flow through the sensing resistor 36 is provided as an input to the RC subcircuit 34, as shown in FIGS. 2-4, where input Vsense is noted in FIGS. 3 and 4.

As shown in FIG. 3, the generated voltage may be amplified by an amplifier 40, if desired, and the output from the amplifier 40 may be provided to the RC subcircuit 34. The RC subcircuit 34 includes one or more resistors and one or more capacitors arranged to provide an output that approximates the temperature of the resistive load 28. The amplifier 40 may thus provide a greater voltage to the RC subcircuit 34 that enables faster charging of the capacitor(s) in the subcircuit and improved response from the subcircuit, as well as a signal that is more easily distinguished from noise or variations in the circuit and in use of the circuit.

In general, the components of the RC subcircuit 34 are selected to provide an output voltage to a comparator 42 that approximates or corresponds to the temperature of the system (e.g. the resistive load 28), and so this output voltage may be used to interrupt discharge of the link capacitor 24 and permit further link capacitor discharge. As explained in more detail below, during a discharge event, the comparator 42 compares the output voltage to a first threshold set to correspond to the maximum temperature threshold, and when the output voltage exceeds the first threshold, the comparator 42 provides an output that is used to interrupt the link capacitor discharge event. Then, the comparator 42 compares the output voltage of the RC subcircuit 34 to a second threshold that is lower than the first threshold and which corresponds to a second, lower temperature threshold, indicating that the system temperature has sufficiently decreased from the maximum temperature. When the output voltage reaches the second threshold, the comparator 42 provides an output that is used to restart discharging of the link capacitor 24. For example, the comparator 42 may be coupled to an interrupt switch 44, shown in FIGS. 2 and 4, which may be a transistor or other switch, as desired, and the comparator 42 may turn the interrupt switch 44 off to selectively interrupt a link capacitor discharge event, and may turn the interrupt switch 44 back on to permit discharge of the link capacitor 24.

In at least some implementations, the capacitance of the RC subcircuit 34 is selected as a function of the thermal mass of conductive elements (e.g. copper) of a circuit board 31, a heat sink, any metal housing or cover surrounding the resistive load 28 and the link capacitor 24. Further, in at least some implementations, the resistance of the RC subcircuit 34 may be selected as a function of the thermal resistance between the center of the resistive load 28 (where temperature may be highest and cooling slowest) to the circuit board 31 and from the circuit board 31 to the ambient environment. Due to the large thermal mass of the system, the temperature rise and fall times can be somewhat long, so the RC subcircuit 34 may include either relatively high capacitance or high resistance. In at least some implementations, a higher capacitance is used as tolerances and reliability of higher value resistors are sometimes poor.

With the RC subcircuit 34 arranged as described, the subcircuit 34 may be used to control the discharging of the link capacitor 24 as a function of the temperature rise caused by the discharge. The rate at which the temperature increases during a discharge event and the rate at which the temperature decreases after a discharge event can be modeled and/or determined empirically. This information can be used in a control scheme when discharge is interrupted to permit a desired cooling of the system before enabling further discharge (e.g. a subsequent discharge event). In this way, system temperature thresholds may be set as a first or maximum temperature (at which discharge is terminated/disrupted) and a lower, second temperature at which discharge may be initiated again (e.g. after a sufficient period of time to achieve a desired temperature reduction).

In at least some implementations, the rate of temperature increase during a discharge event is much greater than the rate of temperature decrease during a cool down period. In one example, the temperature increase from ambient to the maximum temperature threshold took about 4 seconds and the temperature decrease cycle from the maximum temperature threshold to the lower, second threshold took about 30 seconds. Of course, the durations will vary as a function of the magnitude of energy discharge form the link capacitor 24, the resistance of the resistive load 28, and the thermal mass and thermal resistance of the system.

Turning now to the implementation shown in FIG. 4, the RC subcircuit 34 includes a first resistor RI coupled in series with a control capacitor C, and a second resistor R2 coupled in parallel to the control capacitor C. As noted above, the values of the resistors R1 and R2, and of the control capacitor C are chosen as a function of the thermal mass and thermal resistance of the system. In an implementation, RI is chosen as a function of the thermal resistance between the center of the resistive load 28 to the circuit board 31, and sets a relationship between power dissipation and the temperature rise in the system during a discharge event. R2 is chosen as a function of the thermal resistance between from the circuit board 31 to the ambient environment, and sets a relationship between temperature decrease in a cooldown period. The capacitance of control capacitor C is chosen as a function of the thermal mass of the circuit board 31 and metal components like a heat sink and housing in which the circuit board 31 is received.

One way to determine values for the components of the RC subcircuit 34 is to empirically test a system and measuring during link capacitor discharge the temperature rise to the maximum temperature threshold and the temperature decline to the lower, second threshold, over a number of cycles, which provides information regarding the thermal mass and thermal resistance of the system. Further, with a known, maximum output voltage from the amplifier 40 and a selected capacitance value for the control capacitor C, the value of resistors R1 and R2 can be calculated.

In one example, the formulas below were used to determine values of components in the RC subcircuit 34.
Vc(t)=V₀(e^{-t/(R2}*^{C})), to determine the capacitor voltage when discharging;
Vc(t)=(V/(R1*C))((R1*R2*C)/(R1+R2)(1−e^{-t}₀*^{(1/(RI}*^{C)+1/(R2}*^{C)}), to determine the capacitor voltage when charging;
Vh=(V/(R1*C)((R1*R2*C)/(R1+R2))(1−e^{-t}₀*^{(1/(R1}*^{C)+1/(R2}*^{C))}), to determine the voltage output from the RC subcircuit 34 corresponding to the maximum temperature threshold at which a discharge event should be interrupted/terminated for some period of time to permit system cool down, where to is a time to reach maximum temperature during a discharge event from a predetermined temperature (90° C. in one example, an assumed maximum ambient temperature of the resistive load 28);
R2*C=−t_{c}/(ln(Vl/Vh)); where Vl is the voltage output from the RC subcircuit 34 corresponding to the second, lower temperature threshold at which a discharge event may be initiated, where t_{c} is a predetermined time to cooldown from the maximum temperature threshold to the second temperature threshold.

In one example, the voltage of the batteries 18 is about 900 volts, the capacitance of the link capacitor 24 is 270 μF, the total resistance of the resistive load 28 is 3.9 kΩ, the maximum temperature threshold was set at 140° C., the second temperature threshold was set at 105° C., t₀ was 4 seconds, and t_{c} was 30 seconds. From these values, a resistance of R1 was set at 24.25 kΩ, R2 was set at 74 kΩ, and the capacitance of the RC subcircuit 34 capacitor was set at 270 μF.

With these components, the voltage from the RC subcircuit 34 corresponding to the system temperature being at the maximum temperature threshold was about 3.9V, and corresponding to the second temperature threshold was about 0.9V. Accordingly, the comparator 42 is configured to interrupt a discharge event when the output voltage from the RC subcircuit 34 is 3.9V, which is an upper or first threshold that corresponds to the maximum temperature threshold. And the comparator 42 is configured to permit continued discharge of the link capacitor 24 when the output voltage decreased to 0.9V, and may include resistors like those shown, arranged to provide hysteresis that allows the two voltage thresholds.

In use, if the voltage at the RC subcircuit output meets the first threshold, the comparator 42 sends a signal to the interrupt switch 44 to turn that switch off which stops the link capacitor discharge event. When the interrupt switch 44 is off, the comparator 42 is used to check the voltage at the output of the RC subcircuit 34 to the lower, second threshold that corresponds to the second temperature threshold. Because the link capacitor discharge event has been stopped, the energy is now provided by discharge of the RC subcircuit control capacitor 34, and when the voltage at the output of the RC subcircuit 34 then reaches the second threshold, the comparator 42 provides an output to turn the interrupt switch 44 on which enables further discharge of the link capacitor 24. As noted above, the time for the voltage at the RC subcircuit output to decrease from the first threshold to the second threshold via discharge of the RC subcircuit control capacitor C is intended to correspond to the time for the system to sufficiently cool down from the maximum temperature threshold to the second temperature threshold. In other implementations, the RC subcircuit output voltage could be provided to a microcontroller to be monitored, but failure of the microcontroller or a circuit including the microcontroller could prevent proper control of the system.

In at least some implementations, the resistance of resistor R2 in the RC subcircuit 34 can be set higher than the calculated value to, for example, accommodate a decline in capacitance of in the RC subcircuit as can occur over time. Without a higher value for resistor R2, the RC subcircuit 34 will overestimate or overrepresent the temperature of the system potentially causing a premature interruption of a discharge event, and the RC subcircuit 34 will overestimate the cooling, and could enable a premature resumption of link capacitor discharge. Further, the representative model and calculations noted herein provide a RC subcircuit 34 where a zero volt signal occurs at the maximum ambient temperature and if the actual system temperature is lower than this, then the RC subcircuit 34 will overestimate the temperature rise and underestimate the temperature decrease. Other starting/assumed ambient temperatures could be used, if desired. In use, such inaccuracies are not an issue so long as they do not interfere with normal link capacitor discharge events in which the temperature of the system does not reach the maximum temperature threshold, and so no interruption of the discharge event is needed.

Further, the power input to the RC subcircuit 34 is the voltage at the sensing resistor 36, and this scales linearly with current flow and not exponentially as does the energy decrease of the link capacitor 24 during discharge, which could cause the RC subcircuit 34 to underestimate actual power dissipation and thereby underestimate the system temperature increase. The system may be designed somewhat conservatively to normally overestimate the temperature rise or so that any such underestimation is within an acceptable range and the actual temperature of the system components is below a maximum temperature.

Next, the comparator 42 may be of simple design and arranged to provide an output to an interrupt switch 44 connected in series with the discharge switch 30, as shown in FIG. 4, and diagrammatically in FIG. 2. During a discharge event, the comparator 42 compares the voltage at the output of the RC subcircuit 34 to a first threshold and during an interruption of a discharge event, the comparator 42 compares the output voltage to a lower, second threshold. Thus, simple, lower cost analog components can be used to control discharge of a link capacitor 24 as a function of the temperature of components during a discharge event.

The control system may include one or more controllers, and the controllers may be coupled in any desired way and arrangement to the motor(s), batteries, inverter 20, vehicle electrical system and other vehicle components. In order to perform the functions and desired processing set forth herein, as well as the computations therefore, the controllers may include, but not be limited to, a processor(s), computer(s), DSP(s), memory, storage, register(s), timing, interrupt(s), communication interface(s), and input/output signal interfaces, and the like, as well as combinations comprising at least one of the foregoing. For example, a controller may include input signal processing and filtering to enable accurate sampling and conversion or acquisitions of such signals from communications interfaces and sensors.

As used herein the terms control system or controller may refer to one or more processing circuits such as an application specific integrated circuit (ASIC), an electronic circuit, a processor (shared, dedicated, or group) and memory that executes one or more software or firmware programs, a combinational logic circuit, and/or other suitable components that provide the described functionality.

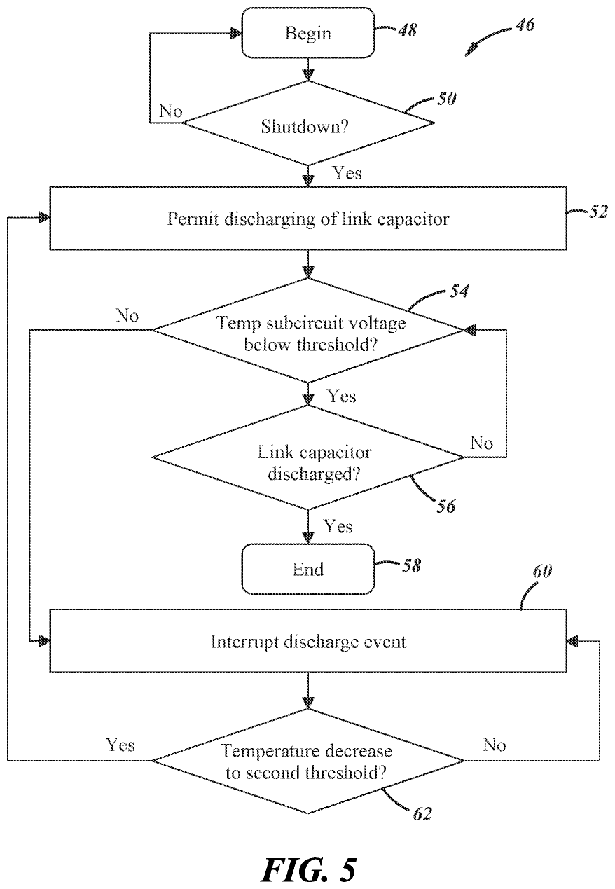

A general method 46 for controlling discharge of the link capacitor 24 is shown in FIG. 5. The method 46 begins at 48 and in step 50 it is determined if the vehicle has been shutdown, which may be determined, for example, by the state of an ignition switch 51 (shown diagrammatically in FIG. 2). If the vehicle has been shutdown, then the discharge switch 30 is closed in step 52 to being a discharge event. Thereafter, in step 54, the system temperature is checked against a maximum temperature threshold. As describe above, the system temperature may be estimated via the RC subcircuit 34 which provides an output voltage that is representative of the system temperature. If RC subcircuit output voltage is below the first threshold, which indicates that the system temperature is less than the maximum temperature threshold, the method continues to step 56 in which it is determined if the link capacitor 24 has been sufficiently or fully discharged, and if that has occurred, the method ends at 58.

If in step 54 it is determined that the system temperature is at or greater than the maximum temperature threshold, then the method continues to step 60 in which the discharge event is interrupted (e.g. by the comparator 42 turning off the interrupt switch 44). Thereafter, in step 62, the RC subcircuit output voltage is checked to determine if it has decreased to the second threshold, which indicates that the system temperature has decreased to the second temperature threshold, and when that has occurred, then the method returns to step 52 and discharging of the link capacitor 24 resumes. A further discharge interruption may occur if the temperature again rises to the maximum temperature threshold, or the link capacitor 24 will be discharged if the temperature does not again rise to that threshold.

In this way, the link capacitor 24 may be discharged while maintaining a system temperature below a threshold, to limit or prevent damage to components that may occur at higher temperatures. In instances in which the temperature subcircuit output voltage remains below the upper threshold, the link capacitor 24 may be fully discharged without interruption. That is, in at least some implementations, interruption occurs only when the voltage of the temperature subcircuit is above an upper threshold indicating that the system temperature is at a maximum temperature threshold.

The temperature circuit may include a simple RC subcircuit 34 having one or more resistors and one or more capacitors, and need not include a temperature sensor like a thermistor or thermocouple. Such a temperature sensor would need to be coupled to the circuit board 31 and presents issues with manufacturing cost and high voltage creepage and clearance distances, because the temperature sensor would be on the low voltage control side of the circuit but must be physically mounted very close to the high voltage active discharge resistor/s to accurately monitor the temperature. Further, due to the difficult physical location of the sensor, the response time can be slow resulting in the resistors operating above their power rating for a longer period of time before the temperature rise has been detected. This can require oversized cooling features to manage the system temperature which increases cost and weight. These complexities and the problems therewith are avoided with the temperature circuit set forth herein, providing a robust, easy to implement and low-cost solution to the problem of an overtemperature condition during a link capacitor discharge event.

All terms used in the claims are intended to be given their broadest reasonable construction and their ordinary meanings as understood by those skilled in the art unless an explicit indication to the contrary is made herein. In particular, use of the singular articles such as “a,” “the,” “said,” etc. should be read to recite one or more of the indicated elements unless a claim recites an explicit limitation to the contrary.

1. A discharge circuit for an electric vehicle, comprising:
a link capacitor;
a resistive load;
a discharge switch coupled to the link capacitor and to the resistive load so that the link capacitor is coupled to the resistive load when the discharge switch is closed to enable discharge of the link capacitor; and
a discharge interrupt assembly having a sensing resistor connected in series with the resistive load, and a temperature circuit, the temperature circuit having an input connected to the sensing resistor and an output, wherein the discharge interrupt circuit is responsive to a voltage at the output of the temperature circuit to open the discharge switch when the voltage from the temperature circuit is higher than a threshold.

2. The circuit of claim 1 wherein the sensing resistor is connected in series with the discharge switch.

3. The circuit of claim 1 which also include an amplifier between the sensing resistor and the temperature circuit.

4. The circuit of claim 1 wherein the link capacitor, resistive load, discharge switch and sensing resistor are connected in series.

5. The circuit of claim 1 wherein the voltage at the output of the temperature circuit is a function of the temperature of the resistive load.

6. The circuit of claim 1 wherein the temperature circuit includes a first resistor, a control capacitor connected in series with the first resistor, and a second resistor coupled in parallel with the control capacitor.

7. The circuit of claim 1 wherein the discharge interrupt assembly includes a comparator coupled to the output of the temperature circuit, wherein the comparator is arranged to provide a first output when a voltage at the output of the temperature circuit is at a first threshold.

8. The circuit of claim 7 wherein the comparator is arranged to provide a second output when the voltage at the output of the temperature circuit is at a second threshold.

9. An electric vehicle, comprising:
a power source;
a motor driven by electricity from the power source;
an inverter coupled to the power source and the motor to convert a DC power output from the power source to AC power and to provide the AC power to the motor;
a link capacitor coupled in series between the power source and the inverter;
a resistive load;
a discharge switch coupled to the link capacitor and to the resistive load so that the link capacitor is coupled to the resistive load when the discharge switch is closed to enable discharge of the link capacitor;
a sensing resistor arranged to receive current when current flows from the link capacitor to the resistive load;
a temperature circuit having an input connected to the sensing resistor and an output; and
a discharge interrupt assembly responsive to a voltage at the output of the temperature circuit to open the discharge switch when the voltage from the temperature circuit is higher than a threshold.

10. The vehicle of claim 9 wherein the discharge interrupt assembly includes a comparator coupled in series with the temperature circuit output, wherein the comparator is arranged to provide an output when a voltage at the output of the temperature circuit is higher than a threshold.

11. The vehicle of claim 9 which also includes an amplifier coupled between the sensing resistor and the temperature circuit.

12. The vehicle of claim 9 wherein the temperature circuit includes a first resistor, a control capacitor connected in series with the first resistor, and a second resistor coupled in parallel with the control capacitor.

13. An electric vehicle, comprising:
a power source;
a motor driven by electricity from the power source;
an inverter coupled to the power source and the motor to convert a DC power output from the power source to AC power and to provide the AC power to the motor;
a link capacitor coupled in series between the power source and the inverter;
a resistive load;
a discharge switch coupled to the link capacitor and to the resistive load so that the link capacitor is coupled to the resistive load when the discharge switch is closed to enable discharge of the link capacitor;
a sensing resistor arranged to receive current when current flows from the link capacitor to the resistive load;
a resistor-capacitor circuit having an input connected to the sensing resistor and an output; and
a comparator coupled to the output of the resistor-capacitor circuit and to the discharge switch and arranged to open the discharge switch when a voltage from the resistor capacitor circuit is higher than a threshold.

14. The vehicle of claim 13 wherein the resistor-capacitor circuit includes a first resistor, a control capacitor connected in series with the first resistor, and a second resistor coupled in parallel with the control capacitor.

15. The vehicle of claim 13 wherein the sensing resistor is connected in series with the discharge switch.

16. The vehicle of claim 13 wherein the link capacitor, resistive load, discharge switch and sensing resistor are connected in series.

17. The vehicle of claim 13 wherein the voltage at the output of the resistor-capacitor circuit is a function of the temperature of the resistive load.

18. The vehicle of claim 13 wherein the comparator is arranged to provide a second output when the voltage at the output of the temperature circuit is at a second threshold.
